(19) United States
(12) Patent Application Publication
(10) Pub. No.: US 2025/0105086 A1
(43) Pub. Date: Mar. 27, 2025

(54) Integrated Circuit Packages and Methods of Forming the Same

(71) Applicant: Taiwan Semiconductor Manufacturing Co., Ltd., Hsinchu (TW)

(72) Inventors: Chun-Yen Lan, Hsinchu (TW); Chih-Chien Pan, Taipei City (TW); Pu Wang, Hsinchu (TW); Li-Hui Cheng, New Taipei City (TW); Ying-Ching Shih, Hsinchu (TW)

(21) Appl. No.: 18/471,739

(22) Filed: Sep. 21, 2023

(51) Int. Cl. H01L 23/367; H01L 23/00; H01L 25/16; H01L 25/18; H10B 80/00

(52) U.S. Cl. CPC H01L 23/3675; H01L 24/29; H01L 24/32; H01L 24/83; H01L 25/165; H01L 24/16; H01L 24/95; H01L 25/18; H01L 2224/16225; H01L 2224/29109; H01L 2224/29111; H01L 2224/29113; H01L 2224/29139; H01L 2224/29144; H01L 2224/29147; H01L 2224/29164; H01L 2224/29169; H01L 2224/29173; H01L 2224/32245; H01L 2224/83444; H01L 2224/83447; H01L 2224/83455; H01L 2224/8346; H01L 2224/95; H10B 80/00

(57) ABSTRACT

Various embodiments include integrated circuit packages and methods of forming integrated circuit packages. In an embodiment, a device includes: a package substrate; an integrated circuit device attached to the package substrate; a stiffener ring around the integrated circuit device and attached to the package substrate; a lid attached to the stiffener ring; a channel connected to an area between the lid and the integrated circuit device, the channel extending along at least one side of the integrated circuit device in a top-down view; and a thermal interface material in the channel and in the area between the lid and the integrated circuit device.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2A-2B are cross-sectional views of die stacks.

FIG. 3 is a cross-sectional view of a package component.

FIGS. 4-10 are views of intermediate stages in the manufacturing of an integrated circuit package, in accordance with some embodiments.

FIGS. 11-12 are views of an integrated circuit package, in accordance with some other embodiments.

FIGS. 13-14 are views of an integrated circuit package, in accordance with some other embodiments.

FIG. 15 is a view an integrated circuit package 100, in accordance with some other embodiments.

FIG. 16 is a view an integrated circuit package 100, in accordance with some other embodiments.

FIG. 17 is a view an integrated circuit package 100, in accordance with some other embodiments.

FIG. 18 is a view an integrated circuit package 100, in accordance with some other embodiments.

FIG. 19 is a view an integrated circuit package 100, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, an integrated circuit package includes a package lid attached to an integrated circuit device with a liquid metal thermal interface material. The integrated circuit package includes features to aid with challenges introduced by using a liquid metal thermal interface material. The integrated circuit package may include channels, into which the thermal interface material may flow when it melts. The formation or redistribution of voids in the thermal interface material may thus be reduced, which may help avoid bleeding of the thermal interface material. Additionally or alternatively, the package lid may include a protruding portion in physical contact with the integrated circuit device to help reduce warpage, which may avoid bleeding of the thermal interface material during warpage. Reliability and/or performance of the integrated circuit package may thus be improved.

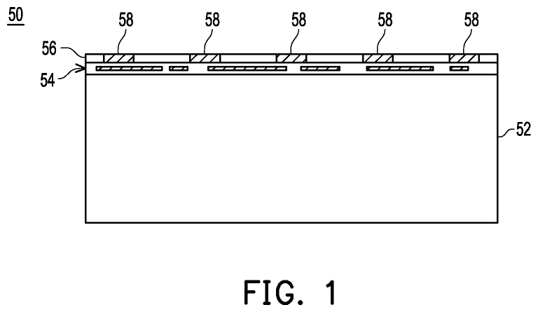

FIG. 1 is a cross-sectional view of an integrated circuit die 50. Multiple integrated circuit dies 50 will be packaged in subsequent processing to form integrated circuit packages. Each integrated circuit die 50 may be a logic die (e.g., central processing unit (CPU), graphics processing unit (GPU), system-on-a-chip (SoC) die, application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different die regions that are singulated in subsequent steps to form a plurality of integrated circuit dies 50. The integrated circuit die 50 may be processed according to applicable manufacturing processes to form integrated circuits. For example, the integrated circuit die 50 includes a semiconductor substrate 52, which may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) may be formed in and/or on the active surface of the semiconductor substrate 52. The devices may be active devices (e.g., transistors, diodes, etc.) and/or passive devices (e.g., capacitors, inductors, resistors, etc.). The inactive surface may be free from devices.

An interconnect structure 54 is disposed over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). The dielectric layer(s) may be, e.g., low-k dielectric layer(s). The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

A dielectric layer 56 is over the interconnect structure 54, at the front-side of the integrated circuit die 50. The dielectric layer 56 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 56 may be formed, for example, by CVD, spin coating, lamination, or the like. Optionally, one or more passivation layer(s) (not separately illustrated) are disposed between the dielectric layer 56 and the interconnect structure 54.

Die connectors 58 extend through the dielectric layer 56. The die connectors 58 may include conductive pillars, pads, or the like, to which external connections can be made. The die connectors 58 may be formed of a suitable conductive material, such as copper, tungsten, aluminum, silver, gold, a combination thereof, or the like, which can be formed by, for example, plating or the like. In some embodiments, the die connectors 58 include bond pads at the front-side of the integrated circuit die 50, and include bond pad vias that connect the bond pads to an upper metallization layer of the interconnect structure 54. In such embodiments, the die connectors 58 (including the bond pads and the bond pad vias) may be formed by a damascene process, such as a single damascene process, a dual damascene process, or the like. The top surfaces of the die connectors 58 and the dielectric layer 56 may be coplanar (within process variations).

Optionally, solder regions (not separately illustrated) may be disposed on the die connectors 58 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 58. Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged. After testing, the solder regions may be removed. In some embodiments, a planarization process such as a chemical mechanical polish (CMP), an etch-back process, combinations thereof, or the like is utilized.

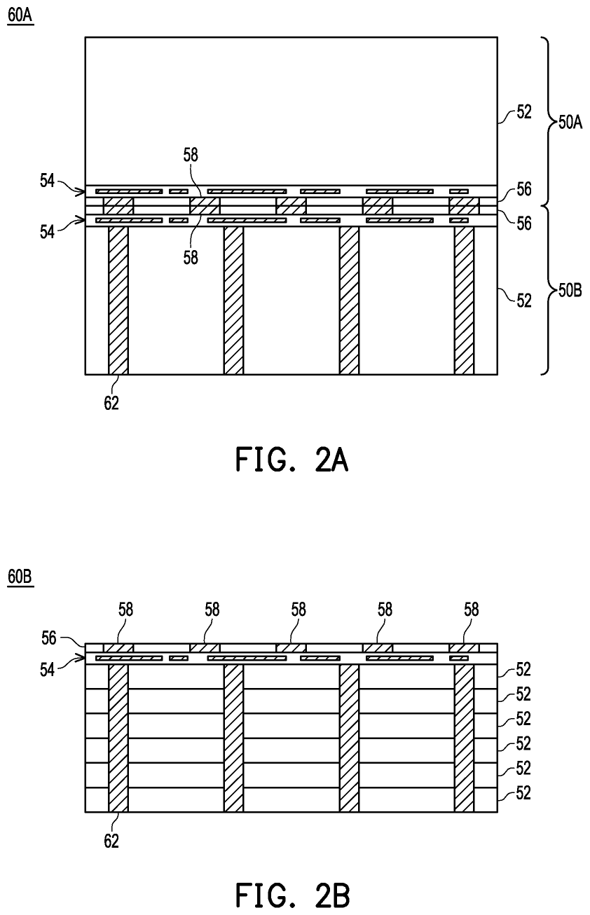

FIGS. 2A-2B are cross-sectional views of die stacks 60A, 60B, respectively. The die stacks 60A, 60B may each have a single function (e.g., a logic device, memory die, etc.), or may have multiple functions. In some embodiments, the die stack 60A is a logic device such as a system-on-integrated-chip (SoIC) device and the die stack 60B is a memory device such as high bandwidth memory (HBM) device.

As shown in FIG. 2A, the die stack 60A includes two bonded integrated circuit dies 50 (e.g., a first integrated circuit die 50A and a second integrated circuit die 50B). In some embodiments, the first integrated circuit die 50A is a logic die, and the second integrated circuit die 50B is an interface die. The interface die bridges the logic die to memory dies, and translates commands between the logic die and the memory dies. In some embodiments, the first integrated circuit die 50A and the second integrated circuit die 50B are bonded such that the active surfaces are facing each other (e.g., are “face-to-face” bonded). Conductive vias 62 may be formed through one of the integrated circuit dies 50 so that external connections may be made to the die stack 60A. The conductive vias 62 may be through-substrate vias (TSVs), such as through-silicon vias or the like. In the illustrated embodiment, the conductive vias 62 are formed in the second integrated circuit die 50B (e.g., the interface die). The conductive vias 62 extend through the semiconductor substrate 52 of the respective integrated circuit die 50, to be physically and electrically connected to the metallization layer(s) of the interconnect structure 54.

As shown in FIG. 2B, the die stack 60B is a stacked device that includes multiple semiconductor substrates 52. For example, the die stack 60B may be a memory device that includes multiple memory dies such as a hybrid memory cube (HMC) device, a high bandwidth memory (HBM) device, or the like. Each of the semiconductor substrates 52 may (or may not) have a separate interconnect structure 54. The semiconductor substrates 52 are connected by conductive vias 62, such as TSVs.

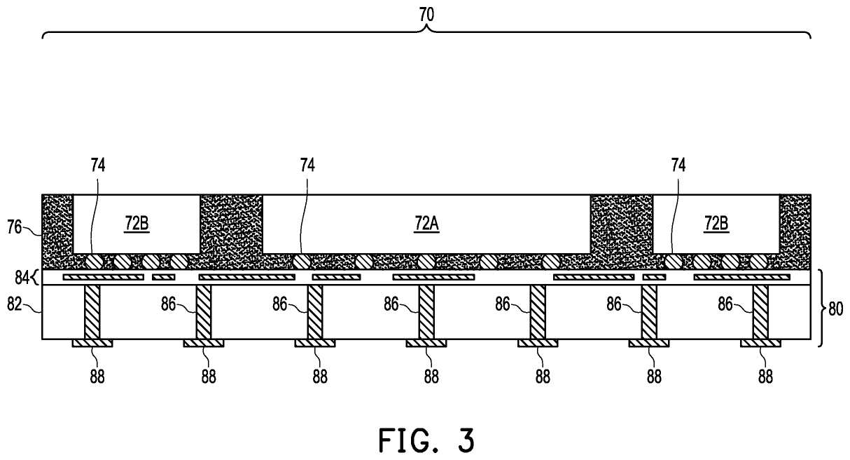

FIG. 3 is a cross-sectional view of a package component 70. The package component 70 includes integrated circuit devices 72 bonded to an interposer 80. The interposer 80 includes a substrate 82, an interconnect structure 84, conductive vias 86, and under bump metallurgies (UBMs) 88.

The substrate 82 may be a bulk semiconductor substrate, a semiconductor-on-insulator (SOI) substrate, a multi-layered semiconductor substrate, or the like. The substrate 82 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 82 may be doped or undoped. In embodiments, the substrate 82 generally does not include active devices therein, although the interposer 80 may include passive devices formed in and/or on a front surface (e.g., the surface facing upward in FIG. 3) of the substrate 82. In embodiments where the interposer 80 includes integrated circuits, active devices such as transistors, capacitors, resistors, diodes, and the like, may be formed in and/or on the front surface of the substrate 82.

The interconnect structure 84 is over the front surface of the substrate 82, and is used to electrically interconnect the devices (if any) of the substrate 82. The interconnect structure 84 may include one or more dielectric layer(s) and respective metallization layer(s) in the dielectric layer(s). The dielectric layer(s) may be, e.g., low-k dielectric layer(s). The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 84 may be formed by a damascene process, such as a single damascene process, a dual damascene process, or the like.

In some embodiments, die connectors (not separately illustrated) are at the front-side of the interposer 80. For example, the interposer 80 may include die connectors that are connected to an upper metallization layer of the interconnect structure 84.

The conductive vias 86 extend into the interconnect structure 84 and/or through the substrate 82. The conductive vias 86 are electrically connected to metallization layer(s) of the interconnect structure 84. The conductive vias 86 may be TSVs. As an example to form the conductive vias 86, recesses can be formed in the interconnect structure 84 and/or the substrate 82 by, for example, etching, milling, laser techniques, a combination thereof, or the like. A thin barrier layer may be conformally deposited in the openings, such as by CVD, atomic layer deposition (ALD), physical vapor deposition (PVD), thermal oxidation, a combination thereof, or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, or the like. Examples of conductive materials are copper, tungsten, aluminum, silver, gold, a combination thereof, or the like. Excess conductive material and barrier layer is removed from a surface of the interconnect structure 84 or the substrate 82 by, for example, a CMP. Remaining portions of the barrier layer and conductive material form the conductive vias 86. The substrate 82 may be subsequently thinned to expose the conductive vias 86 at the back-side of the substrate 82. Exposure of the conductive vias 86 may be accomplished by a thinning process, such as a grinding process, a chemical-mechanical polish (CMP), an etch-back, combinations thereof, or the like.

The UBMs 88 are formed on the exposed surfaces of the conductive vias 86, at the back-side of the of the substrate 82. The UBMs 88 can be formed of a metal, such as copper, aluminum, or the like, and can be formed by, for example, plating, or the like. Conductive connectors for external connection will be subsequently formed on the UBMs 88.

The integrated circuit devices 72 are attached to the front-side of the interposer 80. Multiple integrated circuit devices 72 are disposed adjacent one another. The integrated circuit devices 72 may include one or more logic device(s) 72A and one or more memory device(s) 72B. The logic device(s) 72A and the memory device(s) 72B may be formed in processes of a same technology node, or may be formed in processes of different technology nodes. For example, the logic device(s) 72A may be formed by a more advanced process node than the memory device(s) 72B.

Each logic device 72A may be a central processing unit (CPU), graphics processing unit (GPU), system-on-a-chip (SoC), application processor (AP), microcontroller, or the like. A logic device 72A may be an integrated circuit die (similar to the integrated circuit die 50 described for FIG. 1) or may be a die stack (similar to the die stack 60A described for FIG. 2A). In some embodiments, the logic device(s) 72A are integrated circuit dies such as system-on-a-chip (SoC) dies. In some embodiments, the logic device(s) 72A are die stacks such as system-on-integrated-chip (SoIC) devices.

Each memory device 72B may be a dynamic random access memory (DRAM) die, static random access memory (SRAM) die, hybrid memory cube (HMC) module, a high bandwidth memory (HBM) module, or the like. A memory device 72B may be an integrated circuit die (similar to the integrated circuit die 50 described for FIG. 1) or may be a die stack (similar to the die stack 60B described for FIG. 2B). In some embodiments, the memory device(s) 72B are die stacks, such as high bandwidth memory (HBM) modules.

In the illustrated embodiment, the integrated circuit devices 72 are attached to the interposer 80 with conductive connectors 74, e.g., solder bonds. An underfill (not separately illustrated) may be formed around the conductive connectors 74, and between the interposer 80 and the integrated circuit devices 72. In other embodiments (not separately illustrated), the integrated circuit devices 72 are attached to the interposer 80 with direct bonds, such as with a combination of dielectric-to-dielectric bonds and metal-to-metal bonds. The underfill may be omitted when direct bonding is used. Further, a mix of bonding techniques could be used, e.g., some integrated circuit devices 72 could be attached to the interposer 80 by solder bonds, and other integrated circuit devices 72 could be attached to the interposer 80 by direct bonds.

An encapsulant 76 is formed on and around the various components. The encapsulant 76 encapsulates the integrated circuit devices 72. The encapsulant 76 may be a molding compound, epoxy, or the like. The encapsulant 76 may be applied by compression molding, transfer molding, or the like, and may be formed over the interposer 80 such that the integrated circuit devices 72 are buried or covered. The encapsulant 76 may be applied in liquid or semi-liquid form and then subsequently cured. Optionally, the encapsulant 76 may be thinned to expose the integrated circuit devices 72. The thinning process may be a grinding process, a chemical-mechanical polish (CMP), an etch-back, combinations thereof, or the like.

The package component 70 formed by bonding the integrated circuit devices 72 to a wafer that includes the interposer 80. The encapsulant 76 may be formed around the integrated circuit devices 72 and on the wafer. The structure is then flipped over for processing of the back-side of the wafer. The back-side of the wafer may be thinned to expose the conductive vias 86, and the UBMs 88 may then be formed. The wafer may then be singulated to form the package component 70, which includes a singulated portion of the wafer (e.g., an interposer 80) and the integrated circuit devices 72 which are bonded to that interposer 80. In an embodiment, the package component 70 is a chip-on-wafer (CoW) component, although it should be appreciated that embodiments may be applied to other three-dimensional integrated circuit (3DIC) packages.

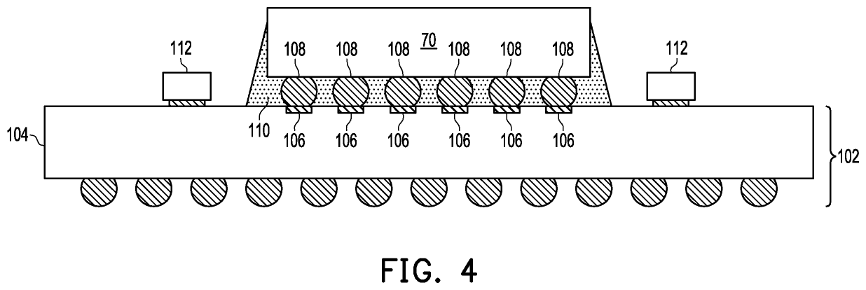

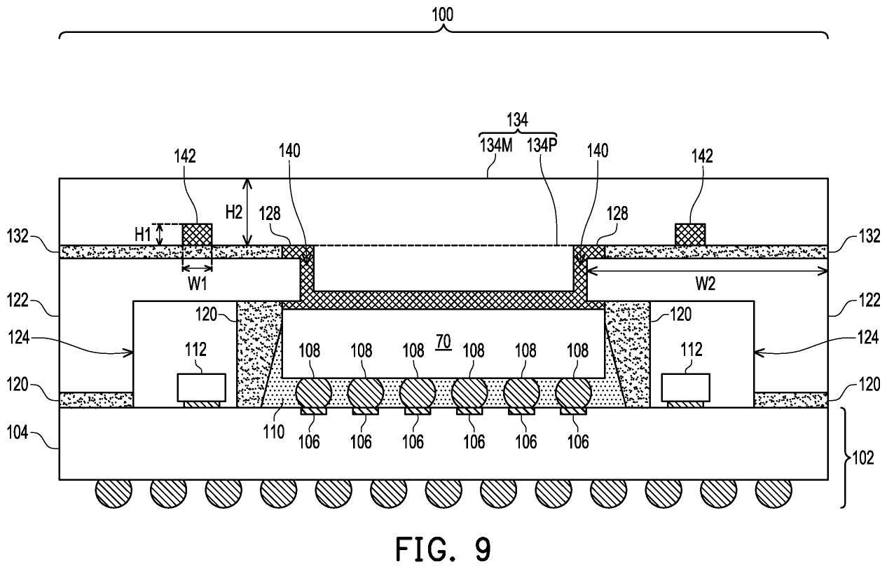

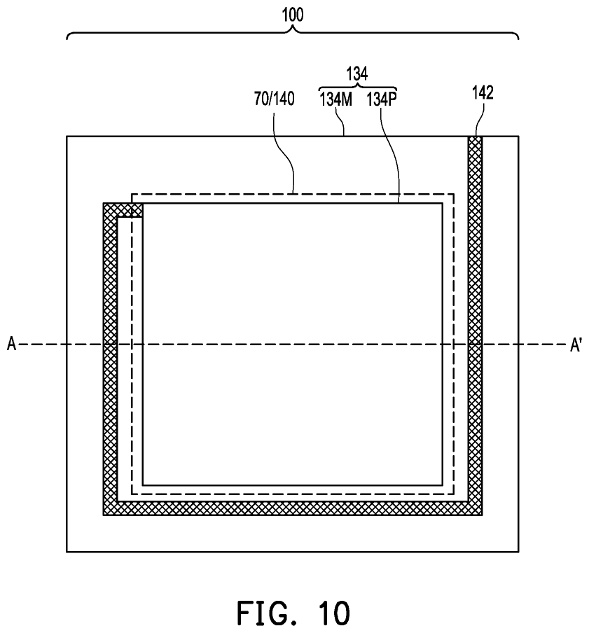

FIGS. 4-10 are views of intermediate stages in the manufacturing of an integrated circuit package 100, in accordance with some embodiments. FIGS. 4, 5, 6, 7, 8, and 9 are cross-sectional views. FIG. 10 is a top-down view. The integrated circuit package 100 is formed by attaching a package component 70 to a package substrate 102. Additionally, a package lid 134 is attached to the package component 70. The resulting integrated circuit package 100 is shown in FIGS. 9-10. In an embodiment, the integrated circuit package 100 is a chip-on-wafer-on-substrate (CoWoS®) package, although it should be appreciated that embodiments may be applied to other 3DIC packages.

In FIG. 4, a package component 70 is attached to a package substrate 102. The package substrate 102 includes a substrate core 104, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 104 may be a SOI substrate. Generally, an SOI substrate includes a layer of a semiconductor material such as epitaxial silicon, germanium, silicon germanium, SOI, SGOI, or combinations thereof. The substrate core 104 is, in one alternative embodiment, an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for substrate core 104.

The substrate core 104 may include active and passive devices (not separately illustrated). Devices such as transistors, capacitors, resistors, combinations thereof, and the like may be used to generate the structural and functional requirements of the design for the system. The devices may be formed using any suitable methods.

The substrate core 104 may also include metallization layers and vias (not separately illustrated) and bond pads 106 over the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper), with vias interconnecting the layers of conductive material, and may be formed through any suitable process (such as deposition, damascene, or the like). In some embodiments, the substrate core 104 is substantially free of active and passive devices.

The package component 70 may be attached to the package substrate 102 with conductive connectors 108, e.g., solder bonds. The conductive connectors 108 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 108 may be formed of a conductive material that is reflowable, such as solder, copper, aluminum, gold, nickel, silver, palladium, tin, the like, or a combination thereof. In some embodiments, the conductive connectors 108 are formed by initially forming a layer of solder through evaporation, electroplating, printing, solder transfer, ball placement, or the like. Once a layer of solder has been formed on the underlying structure, a reflow may be performed in order to shape the material into desired bump shapes. In another embodiment, the conductive connectors 108 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof, which may be formed by a plating process.

Attaching the package component 70 to the package substrate 102 may include placing the package component 70 on the package substrate 102 and reflowing the conductive connectors 108. The conductive connectors 108 are reflowed to attach the UBMs 88 (see FIG. 3) of the package component 70 to the bond pads 106 of the package substrate 102. The conductive connectors 108 connect the package component 70, including metallization layers of the interposer 80 (see FIG. 3), to the package substrate 102, including metallization layers in the substrate core 104. Thus, the package substrate 102 is electrically connected to the integrated circuit devices 72 (see FIG. 3). In some embodiments, passive devices (e.g., surface mount devices (SMDs), not separately illustrated) are attached to the package component 70 (e.g., to the UBMs 88) prior to mounting on the package substrate 102. In such embodiments, the passive devices may be attached to a same surface of the package component 70 as the conductive connectors 108.

In some embodiments, an underfill 110 is formed between the package component 70 and the package substrate 102, surrounding the conductive connectors 108. The underfill 110 may be formed by a capillary flow process after the package component 70 is attached or may be formed by a suitable deposition method before the package component 70 is attached. The underfill 110 may be a continuous material extending from the package substrate 102 to the package component 70.

Additionally, passive devices 112 are attached to the package substrate 102. The passive devices 112 are attached to the same surface of the package substrate 102 as the conductive connectors 108. The passive devices 112 may be attached to the package substrate 102 prior to or after attaching the package component 70 to the package substrate 102. The passive devices 112 may include capacitors, resistors, inductors, the like, or a combination thereof. The passive devices 112 may be surface mount devices (SMDs), 2-terminal integrated passive devices (IPDs), multi-terminal IPDs, or the like.

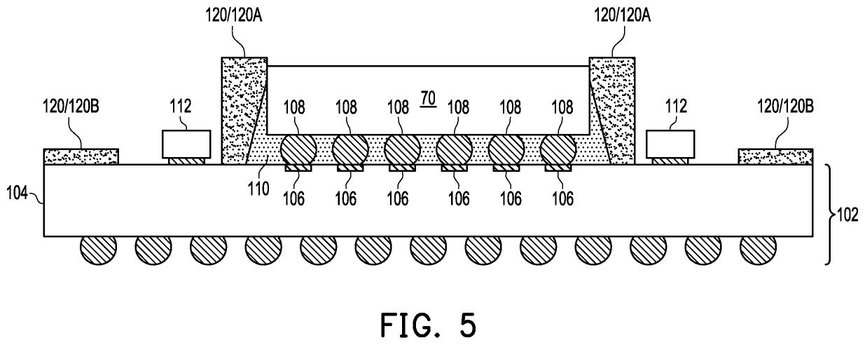

In FIG. 5, an adhesive 120 is formed on the package substrate 102. The adhesive 120 will be used to attach a package stiffener to the package substrate. In some embodiments, first portions 120A of the adhesive 120 are formed on the sidewalls of the underfill 110 and/or the package component 70, while second portions 120B of the adhesive 120 are formed around the passive devices 112 and/or the package component 70. The adhesive 120 may be any suitable adhesive, epoxy, attach film, or the like. The adhesive 120 may be formed in desired locations using a suitable dispensing technique with a stencil having a desired pattern of the adhesive 120. The adhesive 120 may have straight sidewalls (as shown) or may have curved sidewalls (not separately illustrated).

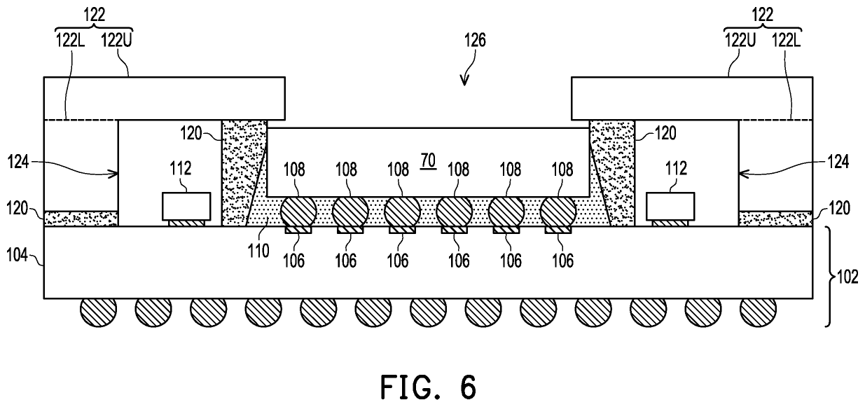

In FIG. 6, a stiffener ring 122 is attached to the package substrate 102 and to the package component 70, using the adhesive 120. The stiffener ring 122 is a package stiffener that helps reduce warpage of the package substrate 102 and the package component 70. The stiffener ring 122 is formed of a rigid material such as copper, aluminum, cobalt, nickel-coated copper, stainless steel, tungsten, a copper-tungsten alloy, a copper-molybdenum alloy, silver diamond, copper diamond, metal diamond composites, aluminum nitride, aluminum silicon carbide, an iron-nickel alloy (e.g., Alloy42), the like, or combinations thereof. In some embodiments, the stiffener ring 122 includes a main body formed of a first metal, and the main body is partially or completely coated with a second metal, such as gold, nickel, a titanium-gold alloy, lead, tin, a nickel-vanadium alloy, or the like. The stiffener ring 122 may be attached to the package substrate 102 by clamping the stiffener ring 122 to the adhesive 120 at a high temperature and curing the adhesive 120.

In this embodiment, the stiffener ring 122 includes an upper portion 122U and a lower portion 122L. The upper portion 122U is above the package component 70. The upper portion 122U is attached to the package substrate 102 using the portions of the adhesive 120 that are on the sidewalls of the underfill 110 and/or the package component 70. The upper portion 122U may be coupled to a periphery of the package component 70, depending on the shape of those portions of the adhesive 120. Thus, the adhesive 120 may (or may not) fills regions where the stiffener ring 122 overlaps with the package component 70. The lower portion 122L is around the periphery of the package component 70. The lower portion 122L is attached to the package substrate 102 using the portions of the adhesive 120 that are around the passive devices 112 and/or the package component 70. The width of the upper portion 122U is greater than the width of the lower portion 122L. The height of the stiffener ring 122 is greater than the height of the package component 70.

The adhesive 120 acts as a dam to seal off an area between the package substrate 102 and the stiffener ring 122 to create a void 124. The void 124 may be around the package component 70 in a top-down view. The stiffener ring 122 overlaps the passive device 112, and as a result, the passive devices 112 are in the void 124. By sealing the void 124 with the adhesive 120, a thermal interface material subsequently formed on the package component 70 may have a reduced risk of flowing to and shorting the passive devices 112, even when the thermal interface material is a liquid.

An opening 126 extends through the middle of the stiffener ring 122. The stiffener ring 122 may be a rectangular ring that is defined by straight horizontal and vertical portions of the stiffener ring 122 in a top-down view. The opening 126 is disposed above the package component 70. The width of the opening 126 may be less than the width of the package component 70. The opening 126 provides an area in which a package lid may be subsequently disposed, such that the package lid may be directly attached to the package component 70. The package lid acts as a heat spreader, and may thus be directly and thermally coupled to the package component 70 (without the stiffener ring 122 being in the thermal path between the package lid and the package component 70), so as to help reduce the formation of hot spots in the package component 70.

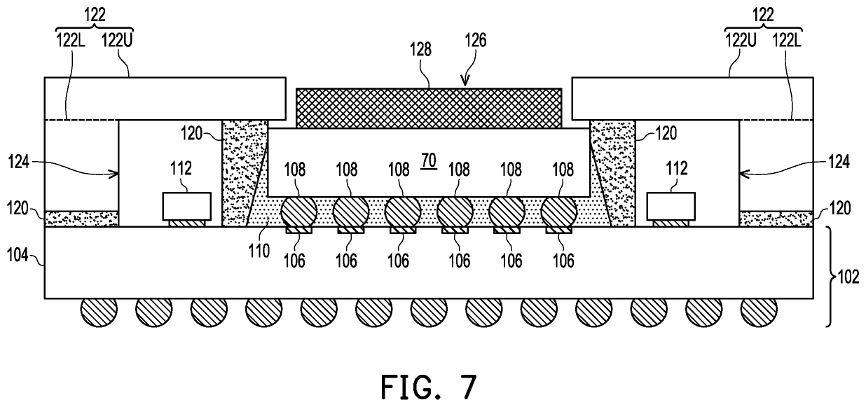

In FIG. 7, a thermal interface material 128 is formed in the opening 126 through the stiffener ring 122, and on the package component 70. The thermal interface material 128 will be used to attach a package lid to the package component 70. The thermal interface material 128 has a high thermal conductivity. In some embodiments, the thermal interface material 128 is a liquid metal. A liquid metal is a metal that melts at a temperature below about 100° C. such that it is in the liquid phase. Acceptable liquid metals may include solder, indium, copper, bismuth, tin, rhodium, palladium, platinum, silver, gold, gallium, combinations thereof, or the like, which are applied in film form or in liquid form. The thermal interface material 128 may be dispensed in the opening 126 and on the package component 70 using a suitable dispensing technique. The thermal interface material 128 may be placed in the opening 126 and on the package component 70 by placing a sheet of liquid metal on the package component 70 using a suitable pick-and-place technique. In some embodiments, the package component 70 lacks back-side metallization, and the thermal interface material 128 may thus be formed directly on the back-side surface of the package component 70 (e.g. the back-sides of the integrated circuit devices 72, see FIG. 3). Use of a liquid metal for the thermal interface material 128 allows for a high amount of heat dissipation to a subsequently-attached package lid, which may be particularly advantageous when the integrated circuit package 100 is used in certain devices, e.g., a high-performance computing (HPC) system, an artificial intelligence (AI) accelerator, or the like. The thermal resistance of a liquid metal may be up to ten times smaller than the thermal resistance of a solid thermal interface material, e.g., a thermal gel.

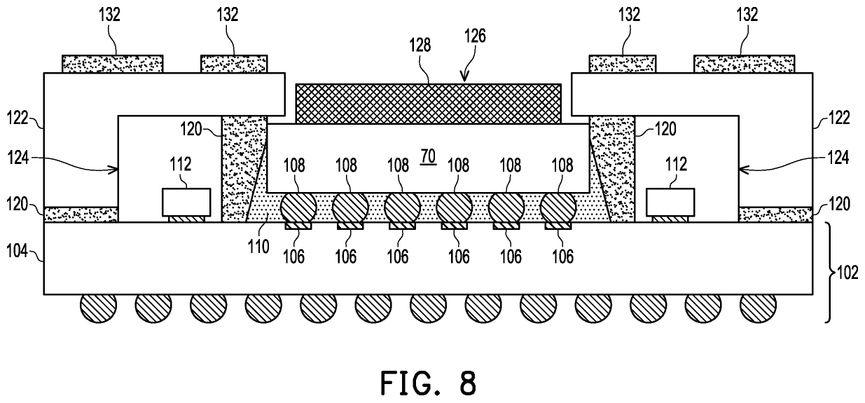

In FIG. 8, an adhesive 132 is formed on the stiffener ring 122. The adhesive 132 will be used to attach a package lid to the stiffener ring 122. The adhesive 132 may be any suitable adhesive, epoxy, attach film, or the like. The adhesive 132 may be formed in desired locations using a suitable dispensing technique with a stencil having a desired pattern of the adhesive 132. As subsequently described in greater detail, the pattern of the adhesive 132 is based on the shape of a channel that will be formed around the package component 70. Specifically, the adhesive 132 is not formed in keep-out regions that are proximate to where the channel will be located.

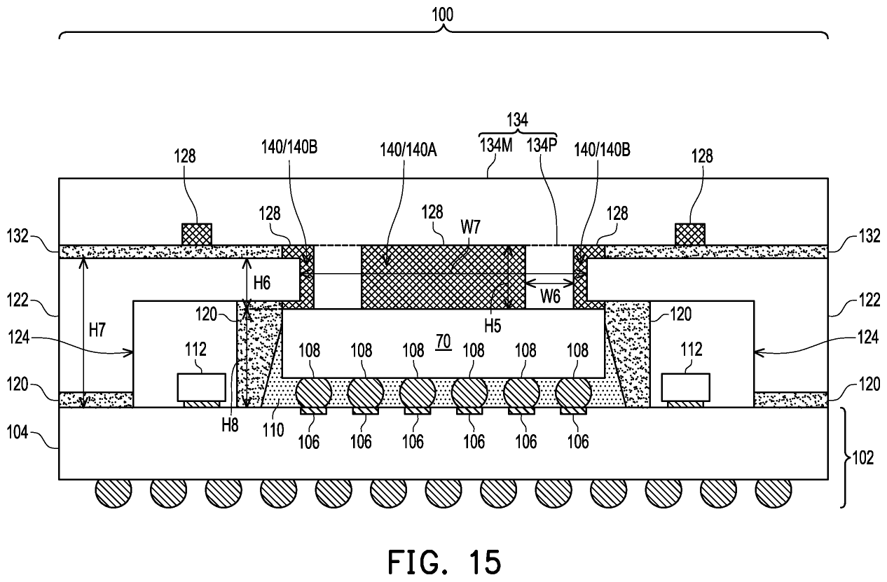

In FIG. 9, a package lid 134 is attached to the stiffener ring 122 and to the package component 70. The package lid 134 may be a thermal lid, a heatsink, a water cooling block, or the like. The package lid 134 may be formed of a material with high thermal conductivity, such as a metal, such as copper, steel, iron, or the like. The package lid 134 may be metallized with a coating such as nickel and/or gold. The package lid 134 protects the package component 70 and forms a thermal pathway to conduct heat from the package component 70. The package lid 134 has a main portion 134M and a protruding portion 134P. The main portion 134M is disposed above the stiffener ring 122, and is attached to the stiffener ring 122 by the adhesive 132. The protruding portion 134P is inserted into the opening 126 (see FIG. 8), and is attached to the package component 70 by the thermal interface material 128. As such, the protruding portion 134P extends through the adhesive 132 and into/through the stiffener ring 122. The width of the protruding portion 134P may be less than the width of the package component 70 and less than the width of the opening 126. In this embodiment, the protruding portion 134P extends into the thermal interface material 128, but is spaced apart from the package component 70 and does not extend through the thermal interface material 128. In other embodiments (subsequently described for FIGS. 15-19), the protruding portion 134P extends through the thermal interface material 128 to physically contact the package component 70. Advantageously, the stiffener ring 122 is not in the thermal path between the package lid 134 and the package component 70. The package lid 134 may be attached to the stiffener ring 122 by clamping the package lid 134 to the adhesive 132 at a high temperature and curing the adhesive 132.

The adhesive 132 at least partially fills regions where the package lid 134 overlaps with the stiffener ring 122. The thermal interface material 128 is disposed in an area 140 between the package lid 134 and the package component 70, the stiffener ring 122, the adhesive 120, and the adhesive 132. The area 140 includes the remaining portion of the opening 126 (see FIG. 8) unoccupied by the protruding portion 134P of the package lid 134. The thermal interface material 128 in the area 140 may extend along a top surface of the package component 70, a bottom surface of the protruding portion 134P of the package lid 134, sidewalls of the stiffener ring 122, and/or sidewalls of the protruding portion 134P of the package lid 134. The thermal interface material 128 in the area 140 may also extend along sidewalls of the adhesive 132.

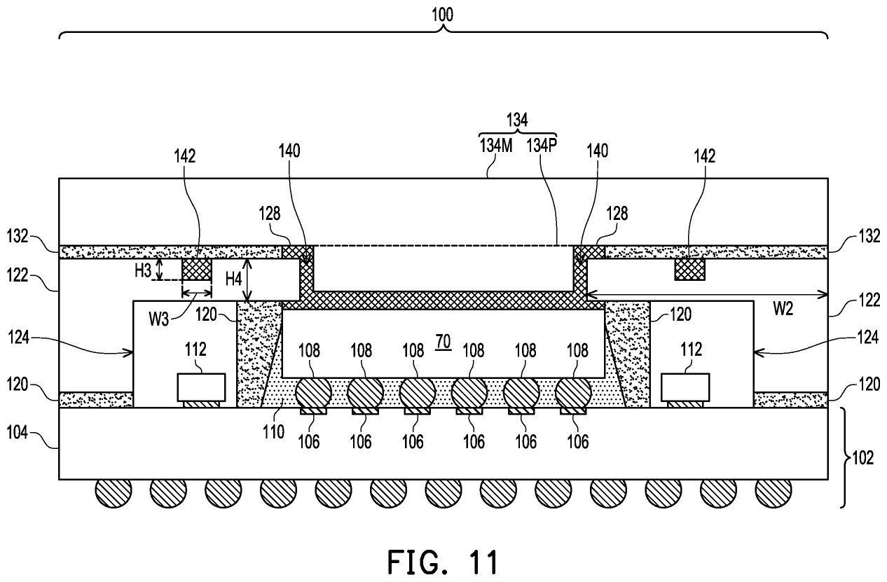

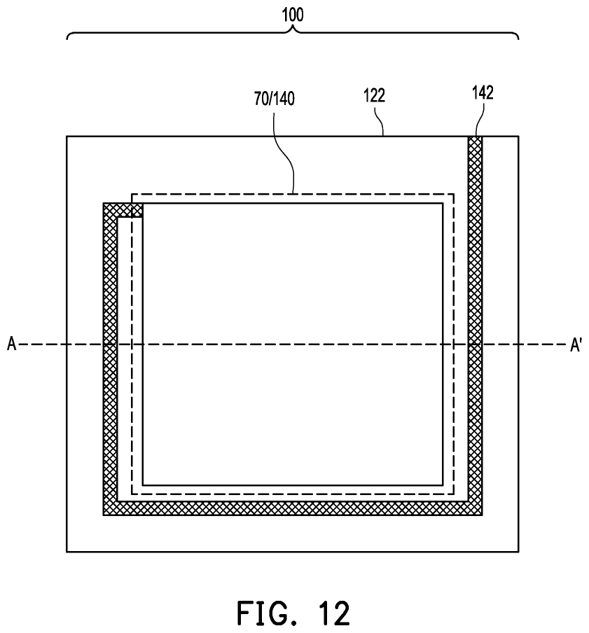

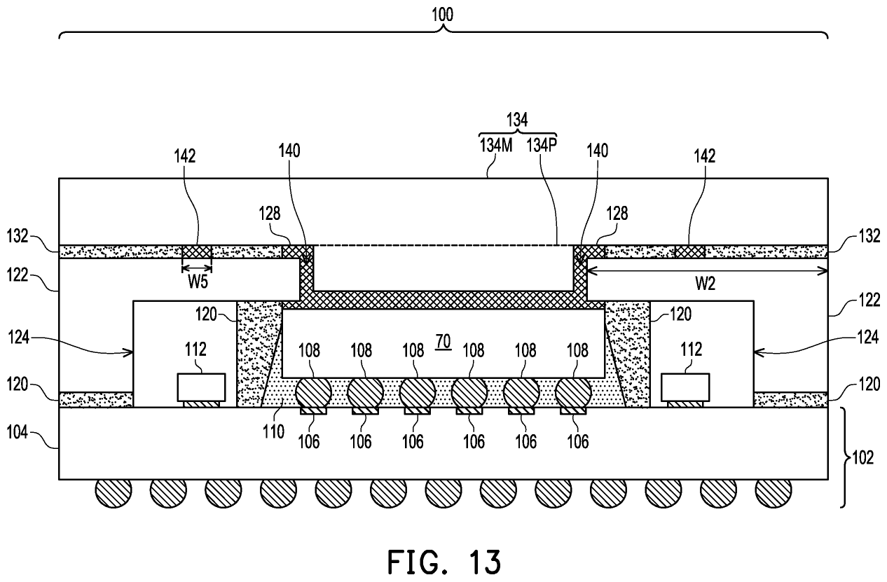

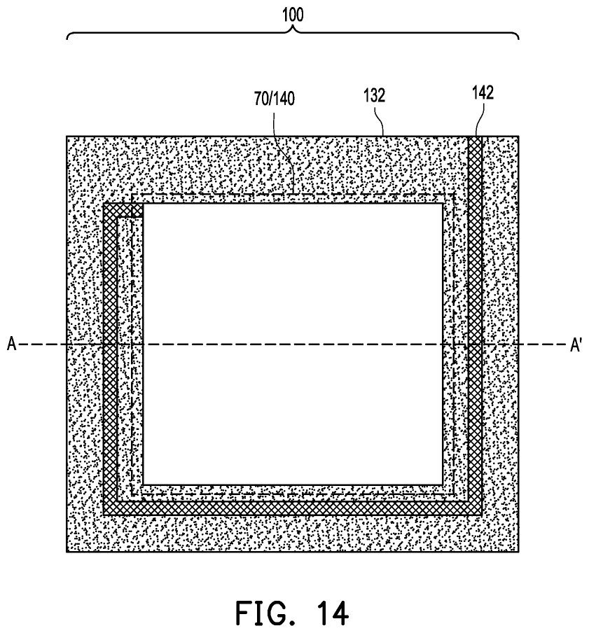

The integrated circuit package 100 further includes a channel 142 for the thermal interface material 128. At least a portion of the thermal interface material 128 may be disposed in at least a portion of the channel 142. In this embodiment, the channel 142 is a groove in the package lid 134. In another embodiment (subsequently described for FIGS. 11-12), the channel 142 is a groove in the stiffener ring 122. In yet another embodiment (subsequently described for FIGS. 13-14), the channel 142 is a groove in the adhesive 132.

FIG. 10 is a top-down view showing the package lid 134 and the channel 142 in greater detail, while other features are omitted or shown in ghost for illustration clarity. FIG. 9 is shown along cross-section A-A′ in FIG. 10. The channel 142 extends from the edge of the package component 70 to the edge of the integrated circuit package 100. The channel 142 is open to the exterior of the integrated circuit package 100 and is open to the area 140. Thus, the channel 142 connects the area 140 to the exterior of the integrated circuit package 100. In this embodiment, the channel 142 connects the exterior of the package lid 134 to the area 140. The channel 142 is a groove in the main portion 134M of the package lid 134 that extends from an outer sidewall of the protruding portion 134P of the package lid 134 to an outer sidewall of the main portion 134M.

The channel 142 extends along at least one side of the package component 70 in the top-down view, and may extend along multiple sides of the package component 70 in the top-down view. In the illustrated embodiment, the channel 142 extends along three sides of the package component 70. The quantity of sides of the package component 70 along which the channel 142 extends may be determined based on the amount of thermal interface material 128 that is expected to flow out of the area 140.

Referring back to FIG. 9, the channel 142 in the package lid 134 has a width W1 and a height H1. The width W1 and the height H1 may be determined based on the amount of thermal interface material 128 that is expected to flow out of the area 140. The width W1 of the channel 142 is less than a width W2 of the upper portion of the stiffener ring 122. The height H1 of the channel 142 is less than a height H2 of the main portion 134M of the package lid 134. In some embodiments, the width W1 is in the range of 500 μm to 10000 μm, the width W2 is in the range of 10000 μm to 50000 μm, the height H1 is in the range of 500 μm to 1000 μm, and the height H2 is in the range of 1000 μm to 3000 μm.

The adhesive 132 may be formed on the stiffener ring 122 in a pattern that is based on the shape of the channel 142. This helps avoid extrusion of the adhesive 132 into the channel 142 in embodiments where the channel 142 is a groove in the package lid 134 or the stiffener ring 122. The adhesive 132 may extrude to be above/below, but not in, the channel 142. Additionally, this allows the channel 142 to be defined in embodiments where the channel 142 is a groove in the adhesive 132.

As previously noted, the thermal interface material 128 may be a liquid metal. The liquid metal may melt and expand as a result of elevated temperatures during processing or operation of the integrated circuit package 100. Because the channel 142 is connected to the area 140 (see FIG. 9), the thermal interface material 128 in the area 140 may flow into the channel 142 when it expands. Additionally, because the channel 142 connects the interior of the integrated circuit package 100 to the exterior of the integrated circuit package 100, it may act as a vent to help equalize pressure within the integrated circuit package 100 during processing or operation. The formation or redistribution of voids in the thermal interface material 128 may be reduced, which may help avoid bleeding of the thermal interface material 128 into undesired regions of the integrated circuit package 100 (e.g., the voids 124), and which may also decrease the thermal resistance and increase the coverage of the thermal interface material 128. Increasing the coverage of the thermal interface material 128 may reduce the formation of hot spots. Reliability and/or performance of the integrated circuit package 100 may thus be improved.

FIGS. 11-12 are views of an integrated circuit package 100, in accordance with some other embodiments. FIG. 11 is a cross-sectional view. FIG. 12 is a top-down view showing the stiffener ring 122 and the channel 142 in greater detail, while other features are omitted or shown in ghost for illustration clarity. FIG. 11 is shown along cross-section A-A′ in FIG. 12. This embodiment is similar to the embodiment of FIGS. 9-10, except the channel 142 is a groove in the stiffener ring 122. Thus, the channel 142 connects the exterior of the stiffener ring 122 to the area 140.

Referring to FIG. 11, the channel 142 in the stiffener ring 122 has a width W3 and a height H3. The width W3 and the height H3 may be determined based on the amount of thermal interface material 128 that is expected to flow out of the area 140. The width W3 of the channel 142 is less than a width W2 of the upper portion of the stiffener ring 122. The height H3 of the channel 142 is less than a height H4 of the upper portion of the stiffener ring 122. In some embodiments, the width W2 is in the range of 10000 μm to 50000 μm, the width W3 is in the range of 500 μm to 10000 μm, the height H3 is in the range of 500 μm to 1000 μm, and the height H4 is in the range of 1000 μm to 3000 μm.

FIGS. 13-14 are views of an integrated circuit package 100, in accordance with some other embodiments. FIG. 13 is a cross-sectional view. FIG. 14 is a top-down view showing the adhesive 132 and the channel 142 in greater detail, while other features are omitted or shown in ghost for illustration clarity. FIG. 13 is shown along cross-section A-A′ in FIG. 14. This embodiment is similar to the embodiment of FIGS. 9-10, except the channel 142 is a groove in the adhesive 132. Thus, the channel 142 connects the exterior of the adhesive 132 to the area 140.

Referring to FIG. 13, the channel 142 in the adhesive 132 has a width W5. The width W5 may be determined based on the amount of thermal interface material 128 that is expected to flow out of the area 140. The width W5 of the channel 142 is less than a width W2 of the upper portion of the stiffener ring 122. In some embodiments, the width W2 is in the range of 10000 μm to 50000 μm and the width W5 is in the range of 500 μm to 10000 μm and.

FIG. 15 is a view an integrated circuit package 100, in accordance with some other embodiments. This embodiment is similar to the embodiment of FIG. 9, except the protruding portion 134P of the package lid 134 extends through the thermal interface material 128 to physically contact the package component 70. Specifically, the protruding portion 134P contacts the top surface of the package component 70, which is the same surface of the package component 70 on which the thermal interface material 128 is disposed.

The package component 70 may warp as a result of elevated temperatures during processing or operation of the integrated circuit package 100. The protruding portion 134P of the package lid 134 being in physical contact with the package component 70 helps reduce such warpage. Specifically, the protruding portion 134P presses against the package component 70 to reduce the amount by which it may warp. Reducing warpage of the package component 70 may help avoid bleeding of the thermal interface material 128 into undesired regions of the integrated circuit package 100 (e.g., the voids 124). The bond line thickness (BLT) of the thermal interface material 128 may thus have increased uniformity. In this context, the “bond line thickness” is the thickness of the thermal interface material 128, above the package component 70.

In this embodiment, the protruding portion 134P of the package lid 134 is ring-shaped in a top-down view (not separately illustrated). Thus, a first portion 140A of the area 140 between the package lid 134 and the package component 70 is encircled by the protruding portion 134P, while a second portion 140B of the area 140 between the package lid 134 and the package component 70 is between the protruding portion 134P and the stiffener ring 122. Some of the thermal interface material 128 is confined within the first portion 140A of the area 140, which may further reduce bleeding of the thermal interface material 128.

The protruding portion 134P of the package lid 134 has a height H5 and a width W6. In contrast to the embodiments of FIGS. 9-14, the height H5 of the protruding portion 134P is greater than a height H6 of the stiffener ring 122 as measured from the top surface of the package component 70. The width W6 of the protruding portion 134P is less than or equal to a width W7 of the opening in the stiffener ring 122. The stiffener ring 122 has a height H7 as measured from the top surface of the package substrate 102. The height H7 of the stiffener ring 122 is greater than a height H8 of the package component 70 as measured from the top surface of the package substrate 102. In some embodiments, the height H5 is in the range of 1000 μm to 2500 μm, the height H6 is in the range of 500 μm to 2000 μm, the height H7 is in the range of 1100 μm to 3000 μm, the height H8 is in the range of 600 μm to 1000 μm, the width W6 is in the range of 300 μm to 3000 μm, and the width W7 is in the range of 9000 μm to 59000 μm.

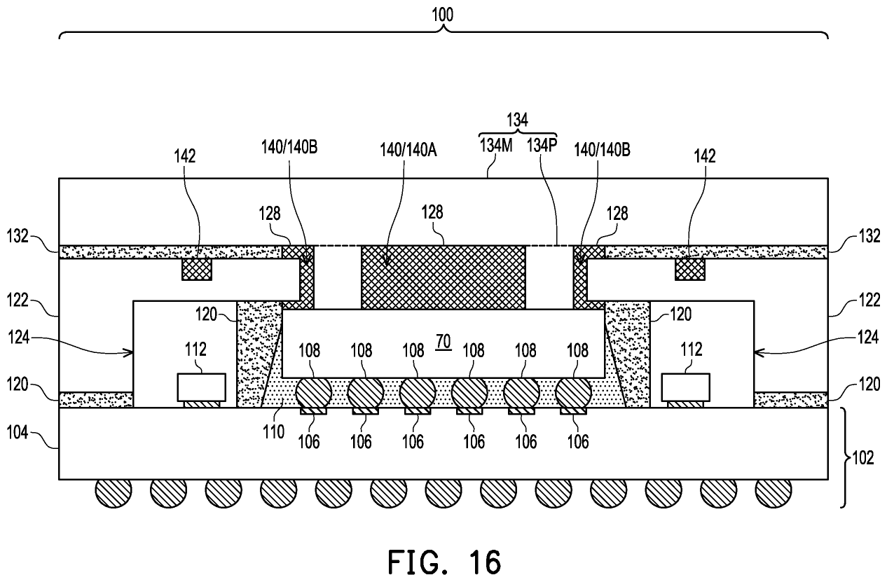

FIG. 16 is a view an integrated circuit package 100, in accordance with some other embodiments. This embodiment is similar to the embodiment of FIG. 15, except the channel 142 is a groove in the stiffener ring 122. Thus, the channel 142 connects the exterior of the stiffener ring 122 to the area 140.

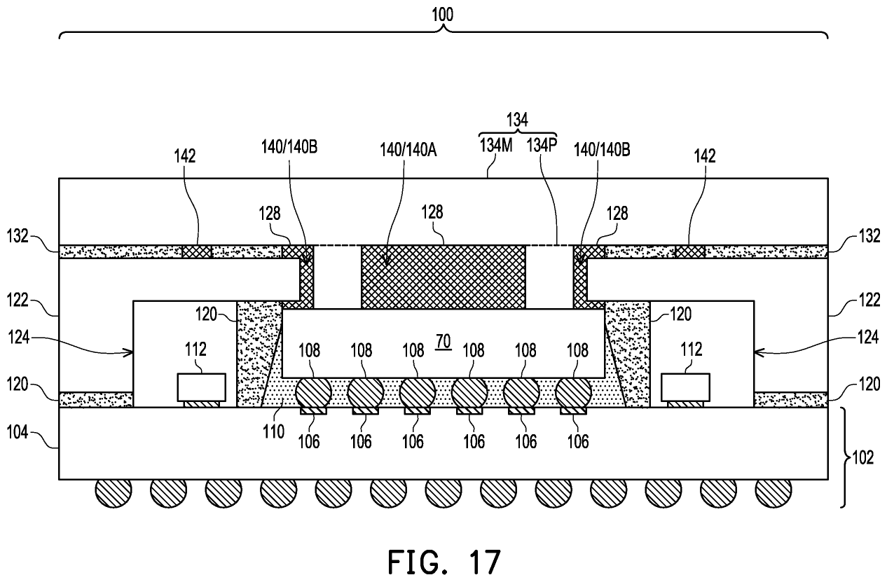

FIG. 17 is a view an integrated circuit package 100, in accordance with some other embodiments. This embodiment is similar to the embodiment of FIG. 15, except the channel 142 is a groove in the adhesive 132. Thus, the channel 142 connects the exterior of the adhesive 132 to the area 140.

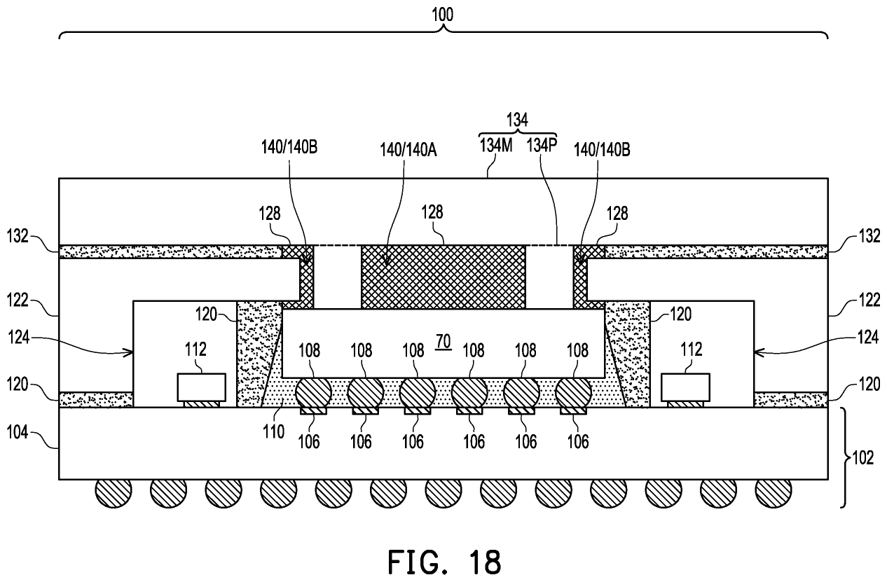

FIG. 18 is a view an integrated circuit package 100, in accordance with some other embodiments. This embodiment is similar to the embodiment of FIG. 15, except the channel 142 is omitted.

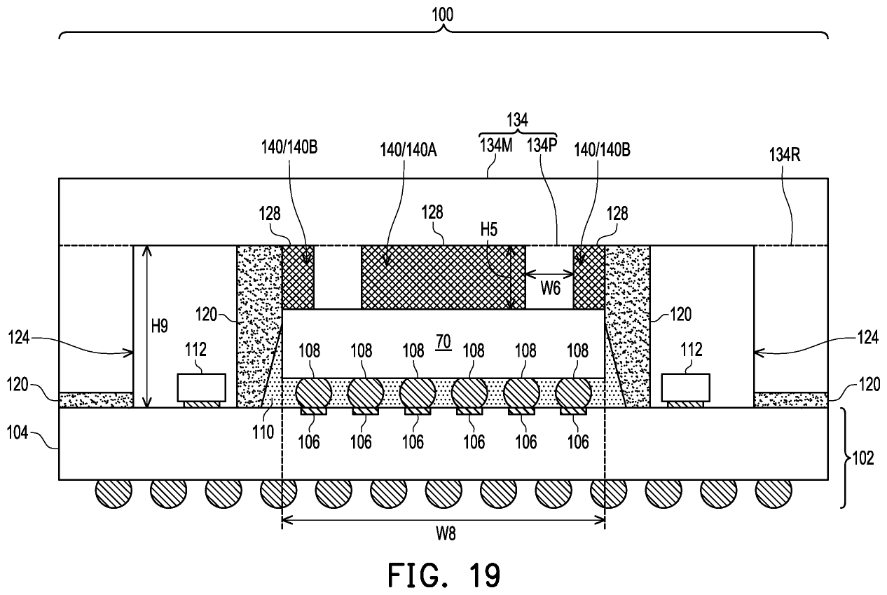

FIG. 19 is a view an integrated circuit package 100, in accordance with some other embodiments. This embodiment is similar to the embodiment of FIG. 18, except the stiffener ring 122 is omitted. Instead, the package lid 134 has a ring portion 134R, in addition to the main portion 134M and the protruding portion 134P. The ring portion 134R is attached to the package substrate 102, and is disposed around the package component 70. Thus, the ring portion 134R functions in a similar manner as a stiffener ring. In this embodiment, the adhesive 120 seals off an area between the package substrate 102 and the package lid 134 to create the void 124.

The ring portion 134R of the package lid 134 has a height H9 as measured from the top surface of the package substrate 102. The height H5 of the protruding portion 134P is less than the height H9 of the ring portion 134R. Additionally, the width W6 of the protruding portion 134P is less than or equal to a width W8 of the package component 70. In some embodiments, the height H9 is in the range of 1200 μm to 3100 μm and the width W8 is in the range of 10000 μm to 60000 μm.

Embodiments may achieve advantages. Utilizing a liquid metal for the thermal interface material 128 within the integrated circuit package 100 may improve thermal dissipation from the integrated circuit package 100. Including the channel 142 provides a location into which the thermal interface material 128 may flow at elevated temperatures (e.g., during processing or operation of the integrated circuit package 100). Thus, the thermal interface material 128 may bleed into controlled regions, thereby reducing the risk of the thermal interface material 128 bleeding into undesired regions. Further, the formation or redistribution of voids in the thermal interface material 128 may be reduced. Additionally, contacting the protruding portion 134P of the package lid 134 to the package component 70 helps reduce warpage of the package component 70 at elevated temperatures. Reliability and/or performance of the integrated circuit package 100 may thus be improved.

In the forgoing embodiments, the integrated circuit package 100 includes a package component 70 attached to a package substrate 102. However, the integrated circuit package 100 may include any type of integrated circuit device (e.g., integrated circuit die, die stack, package component, etc.) attached to the package substrate 102. The package lid 134 is attached to the integrated circuit device.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an embodiment, a device includes: a package substrate; an integrated circuit device attached to the package substrate; a stiffener ring around the integrated circuit device and attached to the package substrate; a lid attached to the stiffener ring; a channel connected to an area between the lid and the integrated circuit device, the channel extending along at least one side of the integrated circuit device in a top-down view; and a thermal interface material in the channel and in the area between the lid and the integrated circuit device. In some embodiments of the device, the channel is a groove in the stiffener ring, and the channel connects an exterior of the stiffener ring to the area between the lid and the integrated circuit device. In some embodiments of the device, the channel is a groove in the lid, and the channel connects an exterior of the lid to the area between the lid and the integrated circuit device. In some embodiments, the device further includes: an adhesive attaching the lid to the stiffener ring, the channel being a groove in the adhesive, the channel connecting an exterior of the adhesive to the area between the lid and the integrated circuit device. In some embodiments of the device, the channel extends along multiple sides of the integrated circuit device in the top-down view. In some embodiments of the device, the thermal interface material is a liquid metal. In some embodiments of the device, a main portion of the lid is disposed above the stiffener ring, a protruding portion of the lid extends through the stiffener ring, and the protruding portion is spaced apart from the integrated circuit device. In some embodiments of the device, a main portion of the lid is disposed above the stiffener ring, a protruding portion of the lid extends through the stiffener ring, and the protruding portion physically contacts the integrated circuit device. In some embodiments, the device further includes: a passive device attached to the package substrate, the stiffener ring overlapping the passive device.

In an embodiment, a device includes: a package substrate; an integrated circuit device attached to the package substrate; a thermal interface material on a top surface of the integrated circuit device; and a lid having main portion on the thermal interface material and a protruding portion extending through the thermal interface material, the protruding portion encircling a portion of the thermal interface material, the protruding portion physically contacting the top surface of the integrated circuit device. In some embodiments, the device further includes: a stiffener ring around the integrated circuit device and attached to the package substrate, the lid being attached to the stiffener ring. In some embodiments of the device, a ring portion of the lid is around the integrated circuit device and attached to the package substrate. In some embodiments of the device, the thermal interface material is a liquid metal. In some embodiments, the device further includes: a channel connected to an area between the lid and the integrated circuit device, the thermal interface material disposed in the channel and in the area between the lid and the integrated circuit device.

In an embodiment, a method includes: attaching an integrated circuit device and a stiffener ring to a package substrate, the stiffener ring disposed around the integrated circuit device, the integrated circuit device exposed by an opening in the stiffener ring; forming a thermal interface material in the opening and on the integrated circuit device; forming an adhesive on the stiffener ring in a pattern corresponding to a channel for the thermal interface material, the channel extending along at least one side of the integrated circuit device in a top-down view; and clamping a lid to the adhesive, a main portion of the lid being disposed above the stiffener ring, a protruding portion of the lid extending through the stiffener ring and into the thermal interface material. In some embodiments of the method, the channel is a groove in the stiffener ring. In some embodiments of the method, the channel is a groove in the lid. In some embodiments of the method, the channel is a groove in the adhesive. In some embodiments of the method, forming the thermal interface material includes dispensing a liquid metal in the opening. In some embodiments of the method, forming the thermal interface material includes placing a sheet of a liquid metal in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a package substrate;
an integrated circuit device attached to the package substrate;
a stiffener ring around the integrated circuit device and attached to the package substrate;
a lid attached to the stiffener ring;
a channel connected to an area between the lid and the integrated circuit device, the channel extending along at least one side of the integrated circuit device in a top-down view; and
a thermal interface material in the channel and in the area between the lid and the integrated circuit device.

2. The device of claim 1, wherein the channel is a groove in the stiffener ring, and the channel connects an exterior of the stiffener ring to the area between the lid and the integrated circuit device.

3. The device of claim 1, wherein the channel is a groove in the lid, and the channel connects an exterior of the lid to the area between the lid and the integrated circuit device.

4. The device of claim 1, further comprising:
an adhesive attaching the lid to the stiffener ring, the channel being a groove in the adhesive, the channel connecting an exterior of the adhesive to the area between the lid and the integrated circuit device.

5. The device of claim 1, wherein the channel extends along multiple sides of the integrated circuit device in the top-down view.

6. The device of claim 1, wherein the thermal interface material is a liquid metal.

7. The device of claim 1, wherein a main portion of the lid is disposed above the stiffener ring, a protruding portion of the lid extends through the stiffener ring, and the protruding portion is spaced apart from the integrated circuit device.

8. The device of claim 1, wherein a main portion of the lid is disposed above the stiffener ring, a protruding portion of the lid extends through the stiffener ring, and the protruding portion physically contacts the integrated circuit device.

9. The device of claim 1, further comprising:
a passive device attached to the package substrate, the stiffener ring overlapping the passive device.

10. A device comprising:
a package substrate;
an integrated circuit device attached to the package substrate;
a thermal interface material on a top surface of the integrated circuit device; and
a lid having main portion on the thermal interface material and a protruding portion extending through the thermal interface material, the protruding portion encircling a portion of the thermal interface material, the protruding portion physically contacting the top surface of the integrated circuit device.

11. The device of claim 10, further comprising:
a stiffener ring around the integrated circuit device and attached to the package substrate, the lid being attached to the stiffener ring.

12. The device of claim 10, wherein a ring portion of the lid is around the integrated circuit device and attached to the package substrate.

13. The device of claim 10, wherein the thermal interface material is a liquid metal.

14. The device of claim 10, further comprising:
a channel connected to an area between the lid and the integrated circuit device, the thermal interface material disposed in the channel and in the area between the lid and the integrated circuit device.

15. A method comprising:
attaching an integrated circuit device and a stiffener ring to a package substrate, the stiffener ring disposed around the integrated circuit device, the integrated circuit device exposed by an opening in the stiffener ring;
forming a thermal interface material in the opening and on the integrated circuit device;
forming an adhesive on the stiffener ring in a pattern corresponding to a channel for the thermal interface material, the channel extending along at least one side of the integrated circuit device in a top-down view; and
clamping a lid to the adhesive, a main portion of the lid being disposed above the stiffener ring, a protruding portion of the lid extending through the stiffener ring and into the thermal interface material.

16. The method of claim 15, wherein the channel is a groove in the stiffener ring.

17. The method of claim 15, wherein the channel is a groove in the lid.

18. The method of claim 15, wherein the channel is a groove in the adhesive.

19. The method of claim 15, wherein forming the thermal interface material comprises dispensing a liquid metal in the opening.

20. The method of claim 15, wherein forming the thermal interface material comprises placing a sheet of a liquid metal in the opening.
